(19) United States
(12) Patent Application Publication
(10) Pub. No.: US 2026/0245818 A1
(43) Pub. Date: Aug. 20, 2026

(54) High-Power Solid-State Relay with Pin Diode

(71) Applicant: Southwest Research Institute, San Antonio, TX (US)

(72) Inventor: Jerry Alan Bishop, Pipe Creek, TX (US)

(21) Appl. No.: 19/055,562

(22) Filed: Feb. 18, 2025

(51) Int. Cl. H01H 47/32

(52) U.S. Cl. CPC H01H 47/32

(57) ABSTRACT

A solid-state relay (SSR) for switching high power radio frequency (RF) signals. The SSR switches the on/off condition of a PIN diode with applied “switch voltages” to an ON current path and an OFF current path through the relay. However, neither of these switch voltage inputs need be switched.

### FEDERALLY SPONSORED RESEARCH AND DEVELOPMENT

This Invention was made with government support under Contract No. FA807518D002/FA807520F0073 awarded by the United States Air Force. The government has certain rights in the invention.

### BACKGROUND OF THE INVENTION

A “high power RF signal” refers to a radio frequency (RF) signal with a significantly elevated power level (amplitude), meaning it transmits a large amount of electromagnetic energy compared to other RF signals. High power RF signals are used in applications where long transmission distances or strong signal strength is required, such as radar systems, broadcast transmitters, and certain industrial applications.

A “high power RF relay” is a passive electronic device that switches and routes high power RF signals. Conventionally, many high-power relays are a mechanical device that operates using an electromagnet to physically move contacts and switch high-power circuits. In comparison, solid-state relays are purely electronic with no moving parts and can switch significantly faster than electromechanical relays.

### BRIEF DESCRIPTION OF DRAWINGS

FIG. 1 illustrates a set of requirements for a high-power RF relay.

FIG. 2 illustrates a conventional pin diode switch.

FIG. 3 illustrates a pin diode solid state relay (SSR) in accordance with the invention.

FIG. 4 illustrates the SSR used for a high frequency coupler for an aircraft antenna.

### DETAILED DESCRIPTION OF THE INVENTION

The following description is directed to a solid-state relay (SSR) for switching high power radio frequency (RF) signals. The SSR switches the on/off condition of a PIN diode with applied “switch voltages” to an ON current path and an OFF current path through the relay. Using this PIN diode, the SSR provides high reliability, high voltage capability, high current capability, and high surge current capability. It has low distortion and fast switching speed. It can be made to have a small physical size and to have thermal packaging.

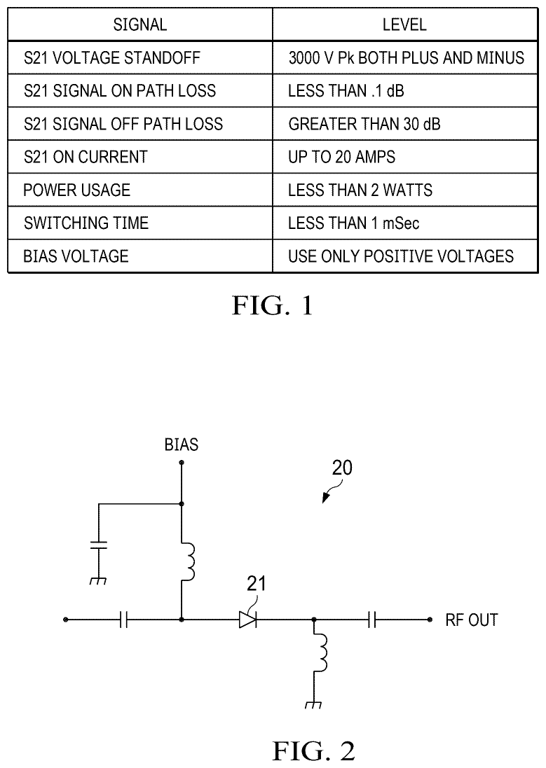

FIG. 1 illustrates a set of design requirements for a relay for a high frequency coupler. As explained below, a high frequency coupler is one example of an application for the SSR described herein, but the SSR may be used for other applications. The S21 requirements are in standard s-parameter signal transmission measurements. A feature of the invention is the recognition that a PIN diode relay can be designed to meet these requirements.

FIG. 2 illustrates a circuit for a conventional PIN diode switch 20. With this conventional design, a bias voltage (BIAS) must be switched between a positive voltage for an ON condition and then to a negative voltage for the OFF condition. More specifically, under zero- or reverse-bias (the “off” state), PIN diode 21 has a low capacitance. The low capacitance will not pass much of an RF signal. Under a forward bias (the “on” state), a typical PIN diode 21 will have a low resistance making it a good conductor. The RF signal (RF OUT) may then pass through the PIN diode switch.

Referring again to FIG. 1, the relay requirements are for very fast voltage switching. Bias voltage switching at the required voltage levels shows that the conventional PIN diode circuit 20 is inadequate. A PIN diode circuit is needed that does not require positive and negative high voltage switching.

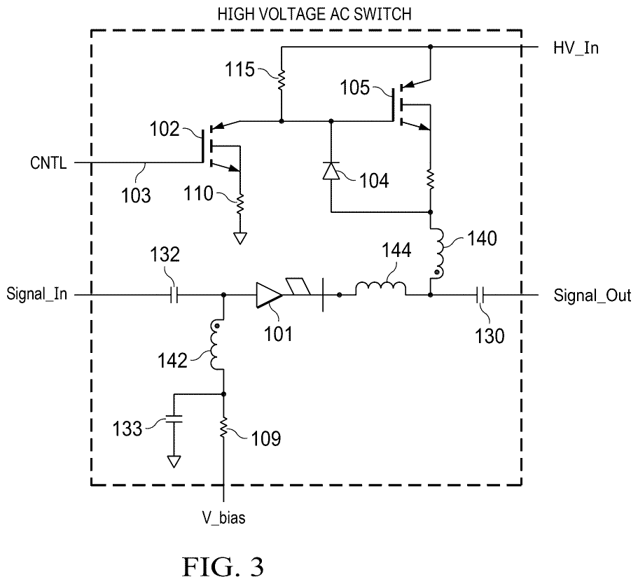

FIG. 3 illustrates a solid-state relay (SSR) 100 implemented as a high voltage AC switch in accordance with the invention. The signal to be switched is identified as Signal-In at an input port and Signal-Out at an output port of the SSR 100. The ON state of SSR 100 is when pin diode 101 is forward biased and provides an ON-signal transmission path between Signal-In and Signal-Out. The OFF state is when pin diode 101 is reverse biased and the signal transmission path is limited.

As explained below, SSR 100 is switched from the ON state to the OFF state by changing the current path through the SSR. Both the forward bias voltage and reverse bias voltage are positive and not required to be switched ON/OFF.

For forward bias, a positive bias voltage (V-bias) is applied to PIN diode 101. When the control (CNTL) level is high (with a small positive voltage) on control line 103, transistor 102 is turned on, which establishes a current path for the V-bias current through diode 101 and then through diode 104 and transistor 102. This reverse biases transistor 105 removing the high voltage (HV) path. An example of a suitable V-bias voltage is 12 volts DC but this could be any small DC voltage greater than 6 volts.

For reverse bias, when the CNTL level is low (GND) transistor 102 is turned off, removing the current path for the V-bias current through PIN diode 101 and reversed bias diode 104. This enables transistor 105 and allows the high positive voltage (HV-In) to be applied to the cathode of PIN diode 101 as a reverse bias voltage.

A feature of SSR 100 is that it can be “hot switched”. In other words, the power need not be removed to change between ON and OFF states.

For the ON state of SSR 100, the CNTL line 103 is set to a positive voltage. For an insulated-gate bipolar transistor that is 10 VDC.

Another power condition for the ON state of SSR 100 is the V-bias current. Resistor 110 and the value of current-limit-resistor 109 set the forward bias current through PIN diodes 101, diode 104, and transistor 102. This forward current applied to PIN diode 101 lowers the ON resistance. The greater the forward current the lower the ON resistance. The voltage drops of transistor 102, diode 104, and inductors 140, 142, and 144 add to the path losses.

In the ON state condition, HV-In has its highest power usage. With transistor 102 enabled, a current path is formed from HV-In to ground through resistor 115 and transistor 102. This current must be kept to a level that will remove the charge in diode 104 and bias transistor 102 to the ON condition within the required time.

For the “OFF” state of SSR 100, the CNTL line 103 is set to ground.

In the “OFF” state of SSR 100, the forward bias current path is removed. The removal of the base voltage on transistor 102 removes the forward bias current path. The V-bias current path is cut off and goes to zero. This also removes the ground on the base of transistor 105, allowing it to conduct. This places the high voltage at the cathode of PIN diode 101.

In the OFF state of SSR 100, the HV-In current operates as follows. With transistor 102 off, transistor 105 will conduct because of the current path through resistor 115. This applies a positive high voltage to the cathode of PIN diode 101. The high voltage current is only needed to remove the stored charge on PIN diode 101. After that time, the current required from the high voltage supply is only for leakage currents.

Thus, for the reasons described above, the only “switch voltage” of SSR 100 that changes state (between low and high) is the CNTL voltage. V-Bias and HV-In are not required to change state (switch on/off). In the ON state of SSR 100, HV-In can stay on because transistor 105 is off. In the OFF state of SSR 100, V-Bias can stay on because transistor 102 is off.

SSR 100 is set up as a SPST (single pole single throw) switch. Signal path capacitors 131, 132, and 133 are chosen to be a low impedance to the frequency band of interest while the inductors 140, 142, and 144 are chosen to be a high impedance at all input frequencies. Inductor 142 is a high impedance path for the RF input but a short to the DC voltage of V-Bias. Similarly, inductor 140 is a high impedance to RF but a short to DC voltage.

The ON path between Signal-In and Signal-Out is when PIN diode 101 is forward biased. The DC current in PIN diode 101 reduces its resistance making the path loss less than 0.1 dB. Inductor 144 was added to series resonate the capacitance of PIN diode 101.

The OFF path is accomplished when the forward DC bias current is blocked by the loss of the V-Bias current path. This applies a large positive voltage (3000 VDC) on the cathode of PIN diode 101. This reverse biases PIN diode 101 and changes it into a large resistance limiting the signal path.

For switch timing, the state change delay comes from the time to charge the coupling capacitor 130 and time to remove the charge from PIN diode 101. This state change timing will be less than 1 mSec.

Timing for the OFF to ON state change is described as follows: The OFF state is when PIN diode 101 is reversed bias by high voltage applied to its cathode. The OFF to ON state change is enunciated by transistor 102 being turned on, which turns off transistor 105 removing the high voltage from the circuit. This now allows the forward bias current to flow through PIN diode 101. This current must pass through the RF choke to charge the intrinsic region of PIN diode 101 which causes a delay in the state change.

From OFF to ON, the forward bias current must flow through all of the inductors 140, 142 and 144. This limits the change rate. Forward current limit is a balance between the ON state power, resistance of PIN diode 101, and the charge time for the state change.

Timing for the ON to Off state change is described as follows: The ON state is when PIN diode 101 is forward biased. A low voltage DC current is flowing through PIN diode 101, which minimizes its intrinsic region making it a small resistance. When transistor 102 is turned off, the current path is removed and the high voltage reverse biases diode 104. Transistor 105 is enabled by the gate current flowing through resistor 115.

The HV-In current is limited by the small gate current for transistor 105. This current is a balance between the ON state power from the HV supply, the charge path through the inductors, and the charge time to reverse bias both PIN diode 101 and coupling capacitor 130.

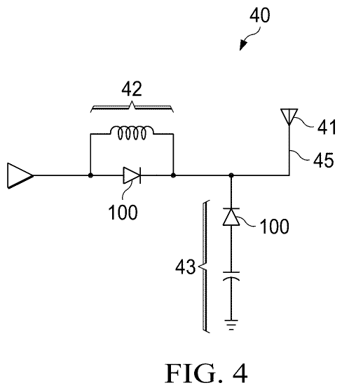

FIG. 4 illustrates an example of an application of SSR 100. Here two SSR's 100 are used in a high frequency coupler 40, which tunes an aircraft antenna 41. SSR 100 switches both a tuning inductor 42 and a tuning capacitor 43 onto a transmission line 45. This function is conventionally achieved with high power vacuum mechanical relays. SSR 100 is a solid-state solution to switch the high level RF signals and may be implemented as a compact unit for airborne applications.

1. A solid-state relay for switching a high-power radio frequency (RF) signal, comprising:
an ON current path through the relay;
an OFF current path through the relay;
a pin diode having a forward bias applied by the ON current path and a reverse bias applied by the OFF current path, wherein the ON current path allows the RF signal to flow from a signal input to a signal output through the relay;
a control voltage input to the base of an ON-path transistor operable to enable the ON-path transistor when set to an on state and to turn off the ON-path transistor when set to an off state;
a V-bias voltage input to a current-limit resistor;
an HV-In voltage input to the collector of an OFF-path transistor;
wherein the ON current path is configured to receive a control voltage at the base of the ON-path transistor, and to transmit a V-bias current via the current-limit resistor, through the PIN diode, through a second diode, to the base of the OFF-path transistor, and through the ON-path transistor to ground; and
wherein the OFF current path is configured to receive an HV-In voltage to the OFF-path transistor, the OFF-path transistor being configured to apply the positive high voltage to a cathode of the PIN diode when the control voltage is in the off state.

2. The solid-state relay of claim 1, further comprising at least one inductor on the ON current path that is high impedance to the RF signal.
